(19) United States
(12) Patent Application Publication
(10) Pub. No.: US 2014/0146507 A1
(43) Pub. Date: May 29, 2014

(54) CIRCUIT BOARD AND SEMICONDUCTOR DEVICE INCLUDING THE SAME

(71) Applicant: Samsung Electronics Co., Ltd., Suwon-si (KR)

(72) Inventor: Jong-Won LEE, Seoul (KR)

(73) Assignee: Samsung Electronics Co., Ltd., Suwon-si (KR)

(21) Appl. No.: 14/045,732

(22) Filed: Oct. 3, 2013

(30) Foreign Application Priority Data
Nov. 27, 2012 (KR) 10-2012-0134963

(51) Int. Cl. H05K 1/11; H05K 1/18

(52) U.S. Cl. CPC H05K 1/111; H05K 1/18
USPC 361/783; 174/267; 174/257

(57) ABSTRACT

In a circuit board for a semiconductor package, the contact pad of the circuit board is partially exposed through a contact hole and a subsidiary pad is provided around the contact hole in such a way that the contact hole is defined by the subsidiary pad. A subsidiary film having the subsidiary pad is provided on a mask pattern for protecting an internal circuit pattern and the contact pad from their surroundings. A contact terminal is provided on the subsidiary film in such a way that the contact hole is at least partially filled with the contact terminal and the subsidiary pad is covered with the contact terminal and an external body is bonded to the contact terminal. The contact area between the circuit board and the contact terminal is enlarged due to the subsidiary pad, thereby increasing the contact reliability of the semiconductor package.

### CROSS-REFERENCE TO RELATED APPLICATIONS

This application claims the benefit of Korean Patent Application No. 10-2012-0134963 filed on Nov. 27, 2012 in the Korean Intellectual Property Office, the disclosure of which is incorporated herein in its entirety by reference.

### BACKGROUND

1. Technical Field

Example embodiments relate to a circuit board and a semiconductor package including the same, and more particularly, to a printed circuit board (PCB) having a high density fine pitch and a semiconductor package including the same.

2. Description of the Related Art

As recent electronic devices have been highly integrated, the semiconductor devices are often manufactured using an area array package rather than a lead frame package on a circuit board. The circuit board has often been also downsized according to the size reduction of the electronic devices.

Therefore, the width and intervals of the linear patterns for internal electric circuits of the circuit board are also often reduced and the contact pad for connecting the internal circuits with an exterior body, such as a memory chip, is also often downsized.

However, the downsizing of the contact pad frequently causes various contact failures between the exterior body and the circuit board, and thus the reliability of the semiconductor package may be deteriorated.

### SUMMARY

Example embodiments of the present disclosed subject matter provide a high density fine pitch circuit board having enlarged a contact surface.

Other example embodiments of the present disclosed subject matter provide a semiconductor package including the above high density fine pitch circuit board.

According to some example embodiments, there is provided a circuit board for enlarging the contact area between the contact board and an external body. The circuit board may include a body, a mask pattern, a subsidiary film and a contact terminal on the subsidiary film. The body may have an internal circuit pattern and a plurality of contact pads connected to the internal circuit pattern and the mask pattern may be positioned on the body in such a configuration that the circuit pattern and the contact pads may be covered with the mask pattern and the mask pattern may have at least a first opening through which the contact pad may be partially exposed. The subsidiary film may be positioned on the mask pattern and may have at least a subsidiary pad in such a configuration that the subsidiary film may have at least a second opening communicating with the first opening to thereby provide a contact hole. The subsidiary pad may be arranged around the second opening to enclose the second opening. The contact terminal may be positioned on the subsidiary film in such a configuration that the contact hole may be filled with the contact terminal and the subsidiary pad may be covered with the contact terminal, so that the contact terminal may make contact with both of the contact pad and the subsidiary pad.

In an example embodiment, the mask pattern may include a solder resist pattern.

In an example embodiment, the subsidiary film may be arranged on the mask pattern in such a configuration that the second opening may be communicated with the first opening and the subsidiary pad may be shaped into a ring enclosing the second opening at an upper portion of the subsidiary film.

In an example embodiment, the subsidiary pad may be arranged on the mask pattern around the second opening in such a configuration that the subsidiary pad may be protruding from the subsidiary film with a stepped portion and the contact hole may be extended to an extended opening penetrating through the ring-shaped subsidiary pad.

In an example embodiment, the circuit board may further include a buffer film positioned on the subsidiary film in such a configuration that an upper surface of the buffer film may be coplanar with an upper surface of the subsidiary pad, thereby removing the stepped portion between the subsidiary film and the subsidiary pad.

In an example embodiment, the subsidiary film may include a recess holding the second opening, and the subsidiary pad may be filled into the recess in such a configuration that the second opening may be defined by the subsidiary pad.

In an example embodiment, the subsidiary film may include one of a polyimide film, a polyoxazole film, a polyamide film and a polyester film and the subsidiary pad may include an electroless plating layer comprising at least one material selected form the group consisting of gold (Au), silver (Ag), copper (Cu), aluminum (Al), nickel (Ni) and combinations thereof.

In an example embodiment, the contact terminal may include solder balls that makes contact with the contact pads, respectively, in a matrix shape.

In an example embodiment, the internal circuit pattern may include a signal line electrically connecting the contact terminal with the contact terminal, a power line applying a power for driving the signal line, a ground line for electrically grounding the signal line and a vertical interconnector penetrating through the body and making contact with the signal lines that are arranged on upper and lower surfaces of the body, respectively.

In an example embodiment, the signal line may have a width of 15 nm to 25 nm and the signal lines may be arranged at a gap distance of 15 nm to 25 nm while the contact pad may have a width of 65 nm to 75 nm and may be spaced apart from the signal line at a gap distance of 15 nm to 25 nm.

According to some example embodiments, there is provided a semiconductor package having the above-described circuit board. The semiconductor package may include a circuit board of which the contact area may be enlarged and having a plurality of contact terminals, a plurality of additional contact terminals positioned at opposite to the plurality of the contact terminals at the circuit board and making contact with both of contact pad and subsidiary pad, and at least an external body having an integrated circuit device and making contact with the additional contact terminal. The circuit board may include a subsidiary pad around the contact hole through which a contact pad may be partially exposed and a subsidiary film having the subsidiary pad may be provided on a mask pattern.

Particularly, the circuit board may include a body, a mask pattern, a subsidiary film and a contact terminal on the subsidiary film. The body may have an internal circuit pattern and a plurality of contact pads connected to the internal circuit pattern and the mask pattern may be positioned on the body in such a configuration that the circuit pattern and the contact pads may be covered with the mask pattern and the mask pattern may have at least a first opening through which the contact pad may be partially exposed. The subsidiary film may be positioned on the mask pattern and may have at least a subsidiary pad in such a configuration that the subsidiary film may have at least a second opening communicating with the first opening to thereby provide a contact hole and the subsidiary pad may be arranged around the second opening to enclose the second opening. The contact terminal may be positioned on the subsidiary film in such a configuration that the contact hole may be filled with the contact terminal and the subsidiary pad may be covered with the contact terminal, so that the contact terminal may make contact with both of the contact pad and the subsidiary pad.

In an example embodiment, the external body may include a semiconductor chip having the integrated circuit device and the additional contact terminal may include a bump structure bonded to an active surface of the semiconductor chip, so that the external body and the additional contact terminal may be provided into a flip chip structure on the circuit board.

In an example embodiment, the external body may include a semiconductor chip having the integrated circuit device and the additional contact terminal may include a penetration electrode penetrating through a substrate of the semiconductor chip and connected to a electrode pad of the semiconductor chip and a bump structure making contact with the penetration electrode at a rear surface of the semiconductor chip, so that the external body and the additional contact terminal may be provided into a chip scale package on the circuit board.

In such a case, the external body may include a plurality of the stacked semiconductor chips and each electrode pad of the semiconductor chips may be electrically connected with each other by the penetration electrode, so that the external body and the additional contact terminal may be provided into a stack package on the circuit board.

In an example embodiment, the external body may include at least an active element and at least a passive element that are arranged on the circuit board.

According to example embodiments of the present disclosed subject matter, the contact pad may be exposed through the contact hole penetrating the mask pattern and the subsidiary film, and the subsidiary pad may be provided around the contact hole. Thus, the external body may make contact with the subsidiary pad as well as the contact pad of the circuit board, so that the contact area between the circuit board and the external body may be enlarged as much as the upper surface area of the subsidiary pad. Therefore, the external body may be secured to the circuit board with high stability and reliability. In addition, the circuit pattern of the circuit board may also be protected from surroundings by the subsidiary film and the subsidiary pad. Although the size and the pitch of the circuit board may be reduced while increasing the number of the external bodies mounted onto the circuit board, the contact area between the external body and the circuit board may be provided due to the subsidiary pad. Therefore, the external body may be bonded to the high density circuit board with high stability and thus the semiconductor package using the circuit board and the electronic system having the semiconductor package may have a high reliability.

### BRIEF DESCRIPTION OF THE DRAWINGS

Example embodiments will be more clearly understood from the following detailed description taken in conjunction with the accompanying drawings.

FIG. 1 is a cross-sectional view illustrating a circuit board in accordance with an example embodiment of the present disclosed subject matter;

FIG. 2 is a plan view illustrating the circuit board shown in FIG. 1;

FIGS. 3A to 3C are cross-sectional views illustrating the configurations of the subsidiary pad 310 and the subsidiary film 300 shown in FIG. 1;

FIG. 4 is a cross-sectional view illustrating a semiconductor package having the circuit board shown in FIG. 1 in accordance with a first example embodiment of the present disclosed subject matter;

FIG. 5 is a cross-sectional view illustrating a semiconductor package having the circuit board shown in FIG. 1 in accordance with a second example embodiment of the present disclosed subject matter;

FIG. 6 is a cross-sectional view illustrating a semiconductor package having the circuit board shown in FIG. 1 in accordance with a third example embodiment of the present disclosed subject matter;

FIG. 7 is a cross-sectional view illustrating a semiconductor package having the circuit board shown in FIG. 1 in accordance with a fourth example embodiment of the present disclosed subject matter; and

FIG. 8 is a structural view illustrating an electronic system having the semiconductor package using the circuit board shown in FIG. 1 in accordance with an example embodiment of the present disclosed subject matter.

### DETAILED DESCRIPTION OF THE EMBODIMENTS

Various example embodiments will be described more fully hereinafter with reference to the accompanying drawings, in which some example embodiments are shown. The present disclosed subject matter may, however, be embodied in many different forms and should not be construed as limited to the example embodiments set forth herein. Rather, these example embodiments are provided so that this disclosure will be thorough and complete, and will fully convey the scope of the present disclosed subject matter to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosed subject matter.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present disclosed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present disclosed subject matter.

Unless otherwise defined, all terms (including technical and scientific terms) used herein have the same meaning as commonly understood by one of ordinary skill in the art to which this disclosed subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

Circuit Board

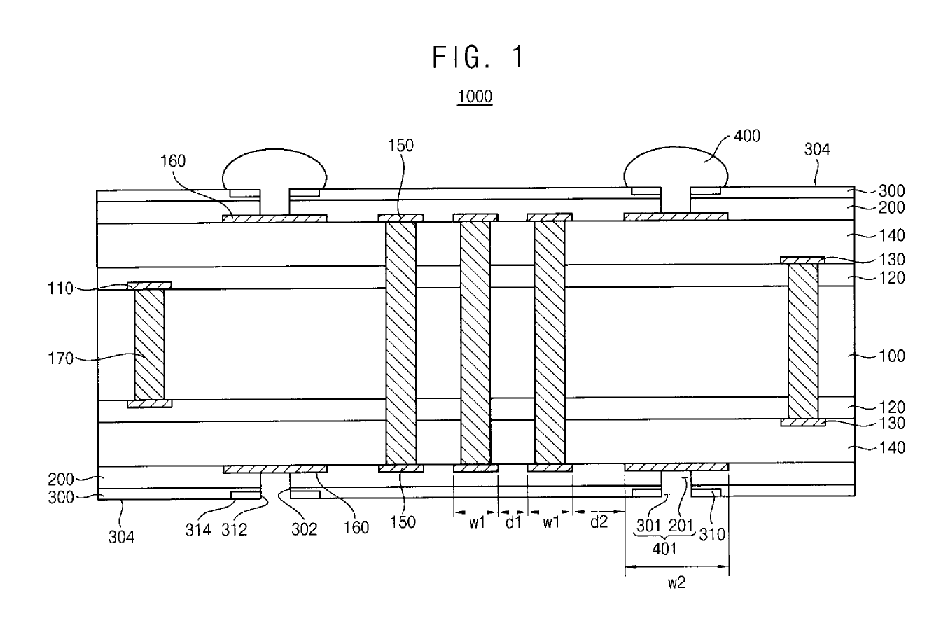

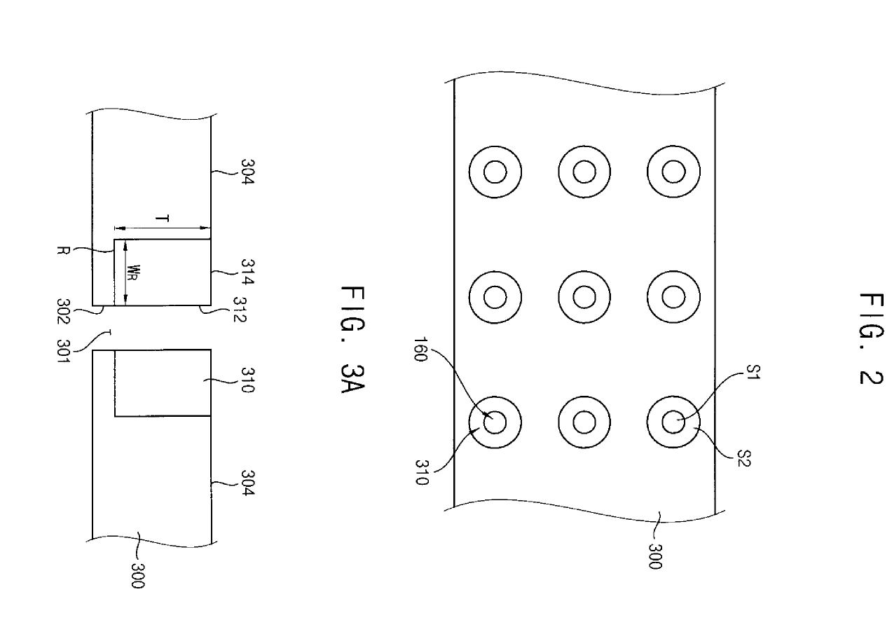

FIG. 1 is a cross-sectional view illustrating a circuit board in accordance with an example embodiment of the present disclosed subject matter. FIG. 2 is a plan view illustrating the circuit board shown in FIG. 1.

Referring to FIGS. 1 and 2, the circuit board 1000 in accordance with an example embodiment of the present disclosed subject matter may include a body 100 having an internal circuit pattern and a plurality of contact pads 160 connected to the internal circuit pattern. The circuit board 1000 may also include, in one embodiment, a mask pattern 200 positioned on the body 100 in such a configuration that the internal circuit pattern and the contact pads 160 may be covered with the mask pattern 200. In various embodiments, the mask pattern 200 may have at least a first opening 201 through which the contact pad 160 may be partially exposed. In some embodiments, the circuit board 1000 may include a subsidiary film 300 positioned on the mask pattern 200 and having at least a subsidiary pad 310 in such a configuration that the subsidiary film 300 may have at least a second opening 301 in communication or connected with the first opening 201 to form a contact hole 401. In some embodiments, the subsidiary pad 310 may be arranged around the second opening 301 to enclose the second opening 301. In some embodiments, the circuit board 1000 may include a contact terminal 400 positioned on the subsidiary film 300 in such a configuration that the contact hole 401 may be filled with the contact terminal 400. In some embodiments, the subsidiary pad 310 may be covered with the contact terminal 400, so that the contact terminal 400 makes contact with both of the contact pad 160 and the subsidiary pad 310.

The body 100 may comprise insulating and heat-resistive materials. In some embodiments, the body 100 may be shaped into a plate having a substantial thickness and rigidity. Thus, the body 100 may, in one embodiment, function as a base of the circuit board 1000. For example, the body 100 may include a thermosetting plastic plate such as an epoxy resin plate and/or a polyimide plate, etc. Otherwise, the body 100 may include a plate on which a heat-resistive organic film, such as a liquid crystal polyester film and/or a polyamide film, etc., may be coated. It is understood that the above are merely a few illustrative examples to which the disclosed subject matter is not limited.

The circuit pattern may include a plurality of conductive lines or wires and may be arranged on upper and lower surfaces of the body 100 using first and second insulation interlayers 120 and 140. Thus, the conductive lines or the wires may be electrically insulated from one another by the first and/or the second insulation interlayer 120 and 140.

For example, a plurality of grounding wires 110 may be arranged on both of upper and lower surfaces of the body 100 and may be covered, at least partially, with the first insulation interlayer 120. Power lines 130 may be configured to apply power to the circuit pattern and may be arranged on the first insulation interlayer 120, and the power lines 130 may be covered with the second insulation interlayer 140. Signal lines 150 and the contact pad 160 may be arranged on the second insulation interlayer 140. The circuit board 1000 and an external body (not illustrated) that is connected with the circuit board 1000 may be electrically communicated with each other via the signal lines 150 and the external body may be connected with the circuit board 1000 at the contact pad 160. In some embodiments, the circuit pattern may include the above grounding wires 110, power lines 130 and signal lines 150.

The first and the second insulation interlayers 120 and 140 and the circuit pattern may be formed on the upper surface and/or the lower surface of the body 100 by a wiring process. For example, the circuit pattern may include a thin metal layer pattern and the insulation interlayers 120 and 140 may include an insulating resin. It is understood that the above is merely one illustrative example to which the disclosed subject matter is not limited.

While the present example embodiment discloses that the grounding wire 110, the power lines 130 and the signal lines 150 may be arranged at, on, or within different insulation layers. In various embodiments, the grounding wire 110, the power lines 130 and the signal lines 150 may be arranged on the same layer.

In addition, while the present example embodiment discloses that the contact pad 160 and the signal lines 150 may be arranged on the second insulation interlayer 140, in another embodiment, the contact pad 160 and the signal lines 150 may also be arranged on different layers according to an allowable vertical thickness margin associated with the semiconductor package, including the circuit board 1000. For example, a third insulation interlayer (not illustrated) may be further formed on the second insulation interlayer 140 to a thickness to cover the signal lines 150 and the contact pad 160 may be formed on the third insulation interlayer. In such a case, the signal lines 150 and the contact pad may be connected with each other through a vertical interconnector that will be described in detail hereinafter.

Since the circuit pattern and the contact pads 160 may be arranged on each of the upper and lower surfaces of the body 100, the circuit pattern on the upper surface may be connected to that on the lower surface through the vertical interconnector 170.

In one such embodiment, the size of the circuit board 1000 may be reduced to a level of high or higher density by reducing the width and the gap distance of the signal lines 150 and the contact pad 160. That is, a first width w1 of the signal line 150 and a first gap distance d1 between the neighboring signal lines 150 may be reduced and the second gap distance d2 between the contact pad 160 and the signal line 150 may also be reduced. In such an embodiment, the number of the signal lines 150 extending along a mounting area between the neighboring contact pads 160 may be increased. Therefore, a larger number of the signal lines 150 may be arranged at the mounting area of the circuit board 1000 between the neighboring contact pads 160 without changing the pitch of the solder balls that may make contact with the contact pads 160. In another embodiment, the pitch of the solder balls may be reduced while the width and the gap distance of the signal lines 150 may be unchanged, thereby increasing the number of solder balls on the circuit board 1000. It is understood that the above are merely a few illustrative examples to which the disclosed subject matter is not limited.

In the present example embodiment, the signal line 150 may have the first width w1 of about 15 μm to about 25 μm. In one embodiment, the neighboring signal lines 150 may be spaced apart by the first gap distance d1 of about 15 μm to about 25 μm. In addition, the contact pad 160 may have the second width w2 of about 65 μm to about 75 μm and may be spaced apart from the signal line 150 by the second gap distance of about 15 μm to about 25 μm.

The mask pattern 200 may be arranged on the second insulation interlayer 140 and the signal line 150 and the contact pad 160 may be covered with the second insulation interlayer 140. The contact pad 160 may be partially exposed through the first opening 201 of the second mask pattern 200.

The mask pattern 200 may have a substantial or a certain level of rigidity and stiffness and thus the external body may be arranged on the circuit board 1000 with substantial or a certain level of reliability. In addition, the heat caused by the operation of a semiconductor device within a package including the circuit board 1000 may be dissipated through the mask pattern 200 and the circuit pattern may be protected from its surroundings by the mask pattern 200. Thus, the mask pattern 200 may have substantial or a certain level of rigidity, heat-resistance and impact resistance.

For example, a sheet (not illustrated) including a thermosetting resin or a thermoplastic resin may be provided on the second insulation interlayer 140 in such a way that the signal line 150 and the contact pad 160 may be covered with the sheet and the sheet may be bonded to the second insulation interlayer 140 by a printing process or a thermo compression bonding process. Then, the bonded sheet may be partially removed in such a way that the contact pad 160 may be partially exposed, thereby forming the mask pattern 200. In various embodiments, the mask pattern 200 may include the first opening 201 through which the contact pad 160 may be partially exposed. Alternatively, the mask pattern 200 that has the first opening 201 may be firstly formed on the second insulation interlayer 140. In such an embodiment, the contact pad 160 may be formed in the first opening. For example, a liquefied resin solution may be coated on the second insulation interlayer 140 and the coated resin solution may be hardened in such a way that the insulation interlayer 140 may be partially exposed to an opening. Then, conductive materials may be coated on the insulation interlayer 140 exposed through the opening by an electroplating process, to thereby form the contact pad 160 in the opening 201 of the mask pattern 200.

In the present example embodiment, the mask pattern 200 may include a solder resist pattern through which the contact pad 160 may be partially exposed and the external body may make contact with the exposed contact pad 160. For example, the solder resist pattern may include a thermosetting resin or a thermoplastic resin. Examples of the thermosetting resin may include epoxy resin, cyanate ester resin, bismaleimide resin, polyimide resin, polyphenylene ether resin and combinations thereof. Examples of the thermoplastic resin may include liquid crystal polyester (LCP) resin. It is understood that the above is merely one illustrative example to which the disclosed subject matter is not limited.

The subsidiary film 300 may be arranged on the mask pattern 200 and may have the second opening 301 that may be connected with the first opening 201, to thereby form the contact hole 401. The conductive subsidiary pad 310 may be arranged around the second opening 301 in such a way that the second opening 301 may be enclosed by the subsidiary pad 310, and an upper surface (or external surface) 314 of the subsidiary pad 310 may be substantially coplanar with an upper surface 304 of the subsidiary film 300. In the present example embodiment, the subsidiary pad 310 may be provided together with the subsidiary film 300 in one body.

The subsidiary film 300 may have good adhesive qualities with respect to the mask pattern 200 and the subsidiary pad 310, and further provide substantial or a certain level of heat-resistance and wear-resistance.

In addition, the subsidiary film 300 may have as small of a thickness as possible so as to minimize the vertical thickness of the circuit board 1000. In the present example embodiment, the mask pattern 200 may have a thickness of about 50 μm to about 100 μm and the subsidiary film 300 may have a thickness of about 20 μm to about 30 μm.

For example, the subsidiary film 300 may have substantially the same materials as the mask pattern 200 in view of the adhesion to the mask pattern 200. In the present example embodiment, the subsidiary film 300 may include at least one of a polyimide film, a polyoxazole film, a polyamide film or a polyester film. However, various films may be used as the subsidiary film 300 as long as the film would be adhered to both of the mask pattern 200 and the subsidiary pad 310.

The subsidiary film 300 may be arranged on the mask pattern 200 in such a way that the second opening 301 may be aligned with the first opening 201 and thus the first and the second openings 201 and 301 may form a single contact hole 401. Therefore, the contact pad 160 may be exposed to its surroundings through the contact hole 401 and thus the external body or the contact terminal 400 may make contact with the contact pad 160 via the contact hole 401.

In various embodiments, when the contact pad 160 and the contact hole 401 may be downsized or reduced in size, in an attempt to increase the density of the circuit board 1000, the contact area between the contact pad 160 and the external body or the contact terminal 400 may be reduced. In such an embodiment, the adhesion between the contact pad 160 and the external body or the contact terminal 400 may be deteriorated or reduced.

In such a case, the subsidiary pad 310 around the second opening 301 may be employed to compensate for the reduced contact area. In such an embodiment, the subsidiary pad 310 may be configured to reinforce the adhesion between the contact pad 160 and the external body or the contact terminal 400. For example, the subsidiary pad 310 may be shaped into a ring enclosing the second opening 301 and may comprise a conductive metal such as gold (Au), silver (Ag), aluminum (Al), nickel (Ni) and combinations thereof coated by an electroless plating process.

A side surface (or inner wall) 312 of the subsidiary pad 310 may, in one embodiment, be substantially coplanar with a side surface (or inner wall) 302 of the subsidiary film 300 and thus the contact hole 401 may be defined by both of the subsidiary pad 310 and the subsidiary film 300. In addition, the upper surface 314 of the subsidiary pad 310 may also be substantially coplanar with the upper surface 304 of the subsidiary film 300. Therefore, as shown in FIG. 2, the exposed surface S1 of the contact pad 310 may be continuous with the upper surface 314 of the subsidiary pad 310 in plan view. Thus, the external body or the contact terminal 400 may make contact with the upper surface 314 of the subsidiary pad 310 as well as with the exposed surface S1 of the contact pad 160. In various embodiments, this may improve the adhesion reliability of the circuit board 1000. Furthermore, the subsidiary film 300 may also protect the circuit pattern and the contact pad 160 from their surroundings, thereby increasing the reliability of the circuit board 1000.

The subsidiary pad 310 and the subsidiary film 300 may be provided in various configurations. It is understood that the above are merely a few illustrative examples to which the disclosed subject matter is not limited.

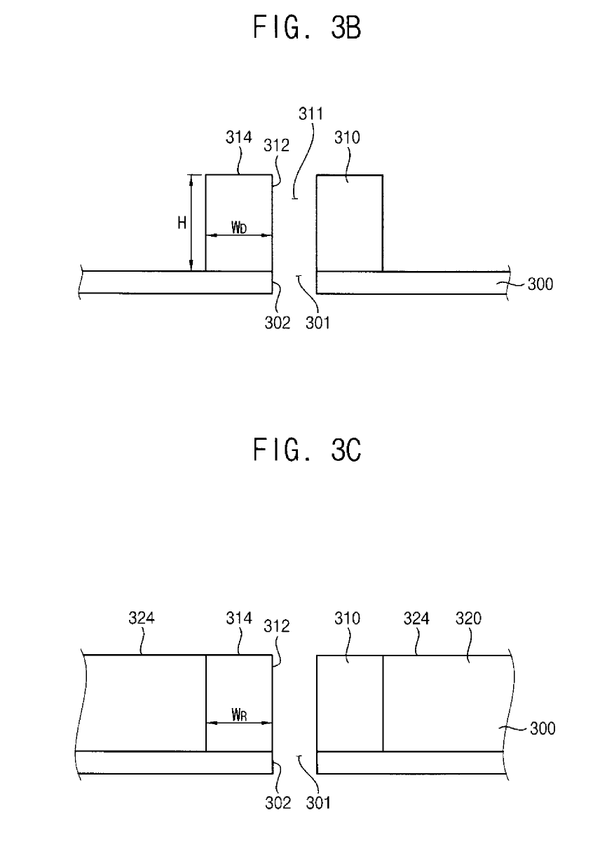

FIGS. 3A to 3C are cross-sectional views illustrating the configurations of the subsidiary pad 310 and the subsidiary film 300 shown in FIG. 1. Referring to FIG. 3A, the subsidiary film 300 may include a recess R that may have a depth T from the upper surface 304 and the subsidiary pad 310 may fill, at least partially, the recess R of the subsidiary film 300.

For example, the recess R may have a recess width W_{R} extending from the second opening 301 and a depth T extending from the upper surface 304 of the subsidiary film 300. Thus, the subsidiary film 300 may include the second opening 301 communicated or connected with the first opening 201. In various embodiments, the subsidiary film 300 may also include the recess R that horizontally extends from the second opening 301 for as long as or a width of the recess width W_{R}.

The subsidiary pad 310 may be arranged in the recess R in such a configuration that the side surface (or inner wall) 312 thereof may be substantially coplanar with the side surface (or inner wall) 302 of the subsidiary film 300. The upper surface 314 may be substantially coplanar with the upper surface 304 of the subsidiary film 300. That is, the subsidiary film 300 and the subsidiary pad 310 may have substantially coplanar surfaces, and the second opening 301 may penetrate through the subsidiary pad 310.

In one embodiment, the contact terminal 400 may make contact with the contact pad 160 exposed through the contact hole 401 and with the side and the upper surfaces 312 and 314 of the subsidiary pad 310. In such an embodiment, the contact area between the contact terminal 400 and the circuit board 1000 may be enlarged as much as the upper surface 314 of the subsidiary pad 310. In such a case, the increase of the contact area may be determined by the size of the recess width W_{R}. Accordingly, the contact reliability of the solder ball may be increased on the circuit board 1000 in spite of the high component density.

Referring to FIG. 3B, the subsidiary pad 310 may be arranged on the subsidiary film 300 around the second opening 301 in such a configuration that the side surface 312 of the subsidiary pad 310 may be substantially coplanar with the side surface 302 of the subsidiary film 300. In such an embodiment, the upper surface 314 of the subsidiary pad 310 may not be coplanar with the upper surface of the subsidiary film 300. Thus, the second opening 301 may extend through the subsidiary pad 310, and the subsidiary pad 310 may protrude from the subsidiary film 300 together with a stepped portion. In the present example embodiment, the subsidiary pad 310 may protrude to a height H together with a pad width W_{D} in such a way that the second opening 301 may extend to an extended opening 311 that penetrates through the subsidiary pad 310. Therefore, the subsidiary pad 310 and the subsidiary film 300 may have a stepped portion corresponding to the height H of the subsidiary pad 310.

In such a case, the contact terminal 400 or the external body may be arranged on the subsidiary film 300 in such a way that the subsidiary pad 310 may be covered with the contact terminal 400 or the external body. That is, in one embodiment, the contact terminal 400 or the external body may make contact with both the subsidiary pad 310 and the subsidiary film 300. In such an embodiment, the contact instability caused by the stepped portion may be ameliorated or alleviated.

Referring to FIG. 3C, a buffer film 320 may be further provided on the subsidiary film 300 and thus the stepped portion between the subsidiary pad 310 and the subsidiary film 300 may be eliminated. Thus, an upper surface (or external surface) 324 of the buffer film 320 may be substantially coplanar with the upper surface 314 of the subsidiary pad 310.

In various embodiments, the buffer film 320 may improve the flatness of the circuit board 1000 by eliminating the stepped portion between the subsidiary pad 310 and the subsidiary film 300, and may absorb an external shock, or a part thereof, as it may act as a buffer layer to protect the circuit pattern and the contact pad 160 from their surroundings. In such an embodiment, the buffer film 320 may function as a buffer layer or a protection layer and thus the circuit board 1000 may have an improved reliability.

For example, the contact terminal 400 may be arranged on the subsidiary film 300 in such a configuration that the contact hole 401 may be filled, at least partially, with the contact terminal 400 and the subsidiary pad 310 may be covered, at least partially, with the contact terminal 400. The contact terminal 400 may make contact with both the contact pad 160 and the subsidiary pad 310.

The contact terminal 400 may, in one embodiment, include a plurality of solder balls that may make contact with a plurality of the contact pads 160, respectively, in a matrix shape. It is understood that the above is merely one illustrative example to which the disclosed subject matter is not limited. In the present example embodiment, the solder ball may include a spherical metal interconnector comprising an alloy of lead (Pb) and tin (Sn). Particularly, at least a supplementary layer (not shown) may be further provided in the contact hole 401 to improve adhering characteristics between the solder ball and the contact pad 160. In addition, an electroplating layer comprising of nickel (Ni), gold (Au) and an alloy thereof may be further provided on the contact pad 160 exposed through the contact hole 401, thereby improving electrical connection between the contact terminal 400 and the contact pad 160. It is understood that the above are merely a few illustrative examples to which the disclosed subject matter is not limited.

In the present example embodiment, the contact hole 401 may be provided with upper and lower surfaces of the circuit board 1000, and the contact terminal 400 may be provided with one of the upper and the lower surfaces of the circuit board 1000. Thus, various external bodies may be arranged on a surface of the circuit board 1000 with which no contact terminal 400 may be provided. The external body may also make contact with the contact pad 160 through the contact hole 401. For example, the external body may include a bump structure. A barrier metal layer (not shown) may be provided along an inner sidewall of the contact hole 401 and the exposed surface of the contact pad 160, and the bump structure may be arranged on the barrier metal layer. In various embodiments, the solder balls or the solder bumps may also be provided with both of the upper and the lower surfaces of the circuit board 1000 according to the structures and configurations of the external body, as would be known to one of the ordinary skill in the art.

The present example embodiment discloses that the circuit pattern may include three pattern layers separated by the first and the second insulation interlayers 120 and 140 on both of the upper and the lower surfaces of the body 100. In some embodiments, the circuit board 1000 may also include further pattern layers separated by additional insulation interlayers according to the requirements of a semiconductor package, including the circuit board and a module including the semiconductor package.

According to example embodiments of the circuit board, the contact pad 160 may be exposed through the contact hole 401 penetrating the mask pattern 200 and the subsidiary film 300, and the subsidiary pad 310 may be provided around the contact hole 401. Thus, the contact terminal or the external body may make contact with the subsidiary pad 310 as well as the contact pad 160, so that the contact area between the circuit board 1000 and the external body or the contact terminal may be enlarged as much as the upper surface area of the subsidiary pad 310. Therefore, the contact terminal 400 and the external body may be secured to the circuit board 1000 with high stability and reliability, and the circuit pattern of the circuit board 1000 may be protected from surroundings by the subsidiary film 300 and the subsidiary pad 310.

In the case of a high density, fine pitch circuit board in which a relatively large number of interconnects (e.g., solder balls, etc.) may be provided despite the size reduction. In such an embodiment, the exposed surface of the contact pad may be reduced due to the reduced size and pitch of the circuit board. However, the present high density, fine pitch circuit board 1000 may include the subsidiary pad in which the upper surface thereof may enlarge the contact area, between the circuit board and the external body, to thereby compensate, at least in part, for the small contact area of the contact pad of the circuit board 1000. In such an embodiment, the contact stability of the circuit board 1000 may be improved by the subsidiary pad 310 and the reliability of the package, including the circuit board, may be increased.

In one embodiment, the solder ball pitch of the circuit board 1000 may be reduced to about 50% as compared with that of the conventional circuit board, and thus the circuit pattern and integrated devices may be mounted on the circuit board 1000 with higher density.

According to the conventional circuit board, the signal lines have a line width and a gap distance of about 20 μm and the contact pad has a width of about 110 μm. Thus, when a pair of the signal lines is provided between a pair of the solder balls, the pair of the solder balls may have a minimal pitch of about 210 μm. However, the width of the contact pad 160 of the present example embodiment of the circuit board 1000 can be reduced to about 70 μm since the subsidiary pad 310 can compensate, at least in part, for the reduced contact area of the contact pad 160. Thus, the minimal pitch of the solder balls, for providing a pair of the signal lines therebetween, may be decreased to about 170 μm on the circuit board 1000. In such an embodiment, the contact pad 160 of the circuit board 1000 may be downsized to about 36% of the contact pad of the conventional circuit board, and the pitch of the solder balls on the circuit board 1000 may be decreased to about 19% as compared with the solder pitch of the conventional circuit board without substantial deterioration of the contact reliability between the contact pad and the solder balls. Accordingly, the circuit board 1000 may have high contact reliability with high density and fine pitch.

Semiconductor Package Having Circuit Board

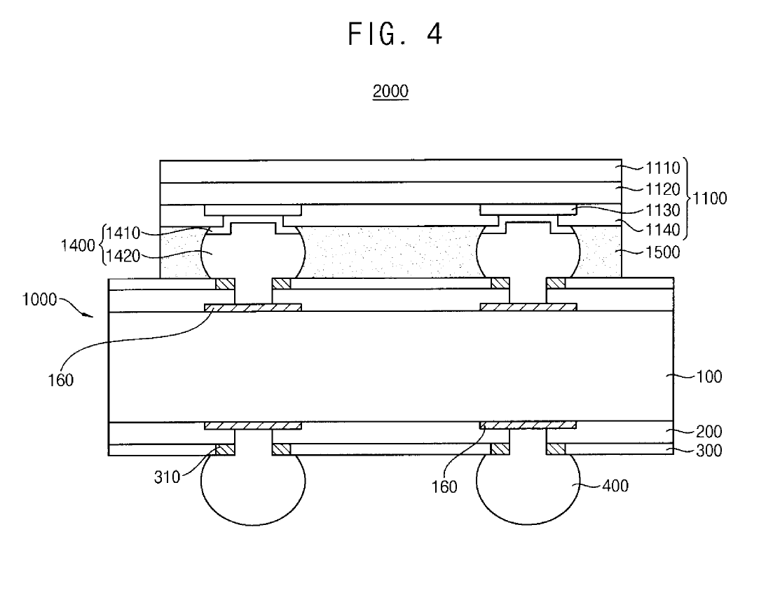

FIG. 4 is a cross-sectional view illustrating a semiconductor package having the circuit board shown in FIG. 1 in accordance with an example embodiment of the present disclosed subject matter.

Referring to FIG. 4, the semiconductor package 2000 in accordance with an example embodiment of the present disclosed subject matter may include a circuit board 1000 having a plurality of contact pads 160 connected with an internal circuit pattern on a first and/or a second surfaces and a plurality of contact terminals 400 making contact with the contact pads 160 at the first surface. In various embodiments, the semiconductor package 200 may include a plurality of additional contact terminals 1400 making contact with the contact pads 160 at the second surface of the circuit board 1000 and an external body 1100 connected to the additional contact terminal 1400. The circuit board 1000 may have substantially the same structure as the circuit board shown in FIG. 1, as described above.

In the present example embodiment, the external body 1100 may include a semiconductor chip having the integrated circuit devices and the additional contact terminal 1400. The external body 1100 may further include a bump structure that may be arranged on an active surface of the semiconductor chip. In one such embodiment, the semiconductor package 2000 may include a flip chip package having the circuit board 1000 shown in FIG. 1.

In various embodiments, the semiconductor chip may include a plurality of conductive structures 1110 stacked on a semiconductor substrate, such as a silicon wafer, using a plurality of insulation interlayers and a plurality of wiring structures 1120 separated from the conductive structures 1110 by the insulation interlayers and transferring signals to the conductive structures 1110. The semiconductor chip may also include an electrode pad 1130, which may be connected with the wiring structure 1120. In various embodiments, the semiconductor chip may include a passivation layer 1140 configured to protect the electrode pad 1130 and the wiring structure 1120 from their surroundings.

For example, the conductive structure 1110 may include a unit structure of a dynamic random access memory (DRAM) device having a pair of transistors and a capacitor; or a unit block of a flash memory device having string transistors, selection transistors. and ground transistors. It is understood that the above are merely a few illustrative examples to which the disclosed subject matter is not limited.

The wiring structure may include a metal plug penetrating through the insulation interlayer and making contact with the conductive structure 1110, and a metal wiring extending on the insulation interlayer and connected to the metal plug. The metal wiring may include a signal line for transferring input/output signals to the conductive structure 1110, a power line for applying an electric power to the conductive structure 1110 and a ground line for electrically grounding the conductive structure 1110.

The input/output signal and the ground signal may be transferred to the conductive structure 1110 via the electrode pad 1130 and the electrode pad 1130 may be electrically connected to the contact pad 160 of the circuit board 1000 through the additional contact terminal 1400. Thus, the conductive structure 1110 of the external body 1100 may be communicated or connected with its surroundings through the electrode pad 1130 and the additional contact terminal 1400. The electrode pad 1130 may be partially exposed through an opening of the passivation layer 1140 and the additional contact terminal 1400 may make contact with the exposed electrode pad 1130.

The additional contact terminal 1400 may make contact with both of the contact pad 160 and the subsidiary pad 310 through the contact hole 401. For example, the additional contact terminal 1400 may include a solder bump structure that may be adhered to the electrode pad 1130 in a medium of an under barrier metal (UBM) layer and may comprise a lead (Pb)-tin (Sn) alloy.

The solder bump structure may be linearly aligned with the contact hole 401 of the circuit board 1000 in a vertical direction and may be compressed onto the circuit board 1000 at a temperature and a pressure. Thus, the solder bump structure may be compressed into the contact hole 401. In such an embodiment, the solder bump structure may be bonded to the contact pad 160 in the contact hole 401. Further, the solder bump structure may also be bonded to the subsidiary film 300 and cover, at least partially, the subsidiary pad 310. Therefore, the solder bump structure may make contact with both the contact pad 160 and the subsidiary pad 310. An under filling layer 1500 may be interposed between the external body 1100 and the circuit board 1000 in such a way that the gap space between the external body 1100 and the circuit board 1000 may be filled up with the under filling layer 1500. Thus, the additional contact terminal 1400 may be protected from external shocks. Although not shown in figures, a sealing member (not illustrated) having electromagnetic compatibility (EMC) characteristics may be on a whole surface of the circuit board 1000 to a thickness to cover the external body 1100, thereby sealing the external body 1100 from surroundings.

Particularly, the additional contact terminal 1400 may also make contact with the subsidiary pad 310 as well as with the contact pad 160, thereby increasing the contact reliability between the circuit board 1000 and the additional contact terminal 1400. Although the circuit board 1000 may be downsized and thus the pitch of the neighboring contact holes 401 may be decreased. In various embodiments, the subsidiary pad 310 may enlarge the contact area between the circuit board 1000 and the additional contact terminal 1400. Therefore, a larger number of the external bodies 1100 may be mounted on the fine-pitched circuit board 1000 without substantial deterioration of contact reliability between the additional contact terminal 1400 and the circuit board 1000.

In the present example embodiment, the external body 1100 may include a single chip scale package (CSP) such as a wafer level chip scale package (WLCSP) in which the integrated circuit devices and the bump structures may be packaged with each other by a wafer unit and then may be cut into pieces. However, any other semiconductor devices may be packaged into the external body 1100 as a flip chip package as well as the CSP, as would be known to one of the ordinary skill in the art.

In addition, while the present example embodiment discloses the bump structure as the additional contact terminal 1400, various contact members, such as bonding wires and tape carries, would be used as the additional contact terminal in place of or in conjunction with the bump structure. Of course, the subsidiary pad 310 may also enlarge the contact area with the bonding wire or the tape carrier as well as with the bump structure.

Although the present example embodiment discloses that the active surface of the semiconductor chip may face the contact hole 401 and thus the semiconductor chip may be configured into a flip chip structure, the semiconductor chip may be mounted on the circuit board 1000 in such a way that a rear surface of the semiconductor chip may face the contact hole 401 and thus the electrode pad 1130 may be connected to the contact pad 160 via a penetration electrode.

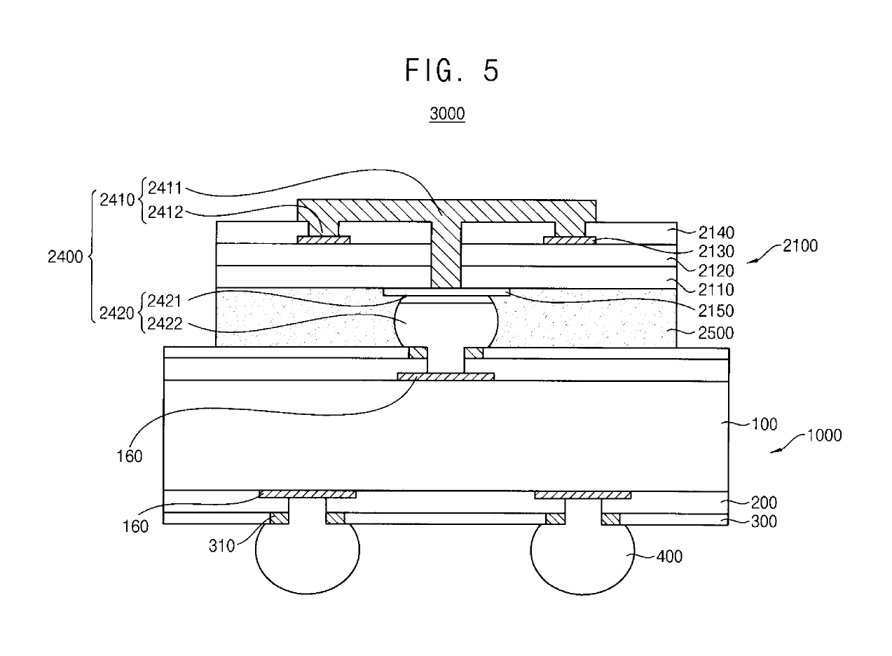

FIG. 5 is a cross-sectional view illustrating a semiconductor package having the circuit board shown in FIG. 1 in accordance with a second example embodiment of the present disclosed subject matter.

Referring to FIG. 5, the semiconductor package 3000 in accordance with a second example embodiment of the present disclosed subject matter may include a circuit board 1000. In various embodiments, the circuit board 1000 may include a plurality of contact pads 160 connecting to an internal circuit pattern on a first and/or a second surfaces and may further include a plurality of contact terminals 400 that make contact with the contact pads 160 at the first surface. In some embodiments, the circuit board 1000 may include a plurality of additional contact terminals 2400 that make contact with the contact pads 160 at the second surface of the circuit board 1000. In various embodiments, the circuit board 1000 may include an external body 2100 that is connected to the additional contact terminal 2400 as well as having at least one integrated circuit device. The circuit board 1000 may have substantially the same structure as the circuit board shown in FIG. 1, so that any further detailed descriptions on the circuit board 1000 will be omitted hereinafter.

In the present example embodiment, the external body 2100 may include a semiconductor chip having the integrated circuit devices, and the additional contact terminal 2400 may include a penetration electrode 2410 penetrating through a semiconductor substrate and making contact with an electrode pad 2130 of the semiconductor chip. The external body 2100 may include a bump structure 2420 that may be arranged on a rear surface of the semiconductor chip, so that the semiconductor package 3000 may include a chip scale package (CSP) having the circuit board 1000 shown in FIG. 1.

The semiconductor chip may include a plurality of conductive structures 2110, a plurality of wiring structures 2120, the electrode pad 2130 and a passivation layer 2140 that may have substantially the same structures as those of the semiconductor chip shown in FIG. 4. Thus, any further detailed descriptions on the conductive structure 2110, the wiring structure 2120, the electrode pad 2130 and the passivation layer 2140 will be omitted hereinafter.

In the present example embodiment, the semiconductor chip of the external body 2100 may include a pair of the electrode pads 2130 extending in a line at a central portion thereof (hereinafter referred to as pad area) and a plurality of memory cells may be arranged at both sides of the pad area (hereinafter referred to as cell area).

The pair of the electrode pads 2130 may be connected to each other by a single penetration electrode 2410, and the penetration electrode 2410 may penetrate through the semiconductor substrate to the bump structure 2420 that may be arranged on the rear surface of the semiconductor chip. Thus, the conductive structure 2110 of the semiconductor chip may be electrically connected to the additional contact terminal 2400 via the bump structure 2420 and the penetration electrode 2410.

For example, the penetration electrode 2410 may include a body electrode 2411 penetrating through the semiconductor substrate and a pair of branch electrodes 2412 diverging from the body electrode 2411 to each of the pair of the electrode pads 2130. Thus, the branch electrodes 2412 may be connected to respective electrode pads 2130. For example, the penetration electrode 2410 may comprise a metal having good electrical conductivity such as titanium (Ti), tantalum (Ta) and tungsten (W). A barrier metal layer (not shown) may be further interposed between the substrate and the penetration electrode 2410.

The body electrode 2411 may protrude from the rear surface of the semiconductor chip and the bump structure 2420 may be connected to the body electrode 2411 at the rear surface via re-directional wirings 2150. Thus, the bump structure 2420 may not, in various embodiments, include or suffer from location limitations due to the re-directional wirings 2150.

The bump structure 2420 may include a under barrier metal (UBM) layer 2421 and a bump body 2422 that may be formed on the UBM layer 2421 by a reflow process. The UBM layer 2421 may make contact with the re-directional wiring 2150 (or with the body electrode when no re-directional wiring may be provided). In various embodiments, the UBM layer 2421 may be configured to substantially prevent the materials of the bump structure 2420 from being diffused into the re-directional wiring 2150. In such an embodiment, this may improve the adherence between the bump body 2422 and the re-directional wiring 2410.

In some embodiments, the bump body 2422 may be arranged on the subsidiary film 300 in such a configuration that the contact hole 401 may be filled, at least partially, with the bump body 2422. In such an embodiment, the bump body 2422 may make contact with the contact pad 160 and the subsidiary pad 310. The bump body 2422 may be linearly aligned with the contact hole 401 of the circuit board 1000 in a vertical direction and may be compressed onto the circuit board 1000 at a temperature and a pressure. Thus, the bump body 2422 may be compressed into the contact hole 401. In such an embodiment, the bump body 2422 may be bonded to the contact pad 160 in the contact hole 401. Accordingly, the bump structure 2420 may be provided on the subsidiary film 300 of the circuit board 1000 in such a configuration that the bump structure 2420 may make contact with both of the contact pad 160 and the subsidiary pad 310.

An under filling layer 2500 may be interposed between the external body 2100 and the circuit board 1000 in such a way that the gap space between the external body 2100 and the circuit board 1000 may be at least partially filled up with the under filling layer 2500.

Thus, the additional contact terminal 2400 may be protected from external shocks. Although not shown in figures, a sealing member (not illustrated) having electromagnetic compatibility (EMC) characteristics may be on a whole surface of the circuit board 1000 to a thickness to cover the external body 2100, thereby sealing the external body 1100 from its surroundings.

The bump structure 2420 may make contact with the subsidiary pad 310 as well as with the contact pad 160. In such an embodiment, this may increase the contact reliability between the circuit board 1000 and the bump structure 2420. Although the circuit board 1000 may be downsized and thus the pitch of the neighboring contact holes 401 may be decreased, the subsidiary pad 310 may enlarge the contact area between the circuit board 1000 and the bump structure 2420. Therefore, a larger number of the external bodies 2100 may be mounted on the fine-pitched circuit board 1000 without deterioration of contact reliability between the bump structure 2420 and the circuit board 1000.

While the present example embodiment discloses that the penetration electrode 2410 may be connected to the circuit board 1000 via the bump structure 2420, various contact members such as bonding wires and/or tape carries may be used in place of or in conjunction with the bump structure 2420. In various embodiments, the subsidiary pad 310 may also enlarge the contact area with the bonding wire or the tape carrier as well as with the bump structure.

In the present example embodiment, the external body 1100 may include a single chip scale package (CSP), such as a wafer level chip scale package (WLCSP), in which the integrated circuit devices and the bump structures may be packaged with each other by a wafer unit and then may be cut into pieces by a chip. However, in some embodiments, other semiconductor devices may be packaged into the external body 2100 as a flip chip package as well as the CSP, as would be known to one of the ordinary skill in the art.

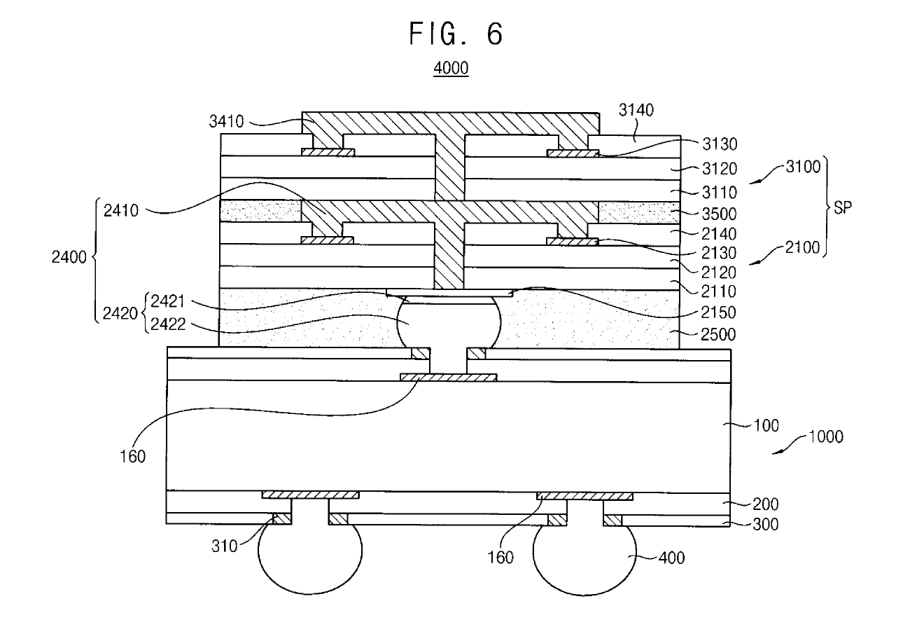

FIG. 6 is a cross-sectional view illustrating a semiconductor package having the circuit board shown in FIG. 1 in accordance with a third example embodiment of the present disclosed subject matter. The semiconductor package 4000 in FIG. 6 may have substantially the same structure as the semiconductor package 3000 shown in FIG. 5, except that an additional external body may be stacked on the external body 2100 by using a penetration electrode. In FIG. 6, the external body 2100 will be referred to as a first external body and the additional external body 3100 positioned on the external body 2100 will be referred to as a second external body. In the same way, the corresponding sub-components of the first and the second external bodies 2100 and 3100 may be also identified as a first sub-component and a second sub-component.

Referring to FIG. 6, the semiconductor package 4000, in accordance with a third example embodiment of the present disclosed subject matter, may include the circuit board 1000, the first external body 2100 on the circuit board 1000 and a second external body stacked on the first external body 3100. The circuit board 1000 and the first external body 2100 may have the same structure as those described with reference to FIG. 5, and thus the detailed descriptions on the external body 2100 and the circuit board 1000 will be omitted hereinafter.

The second external body 3100 may include a second semiconductor chip having integrated circuits on a second semiconductor substrate. A second electrode pad 3130 of the second semiconductor chip may be connected to a second penetration electrode 3410 that may penetrate through the second semiconductor substrate and may be connected to the first penetration electrode 2410. A second under filling layer 3500 may be interposed between the first external body 2100 and the second external body 3100 and thus the gap space between the first external body 2100 and the second external body 3100 may be filled up with the second under filling layer 3500, thereby increasing the contact reliability between the first and the second penetration electrodes 2410 and 3410. Therefore, data signals may be transferred to the second conductive structure 3110 of the second external body 3100 sequentially through the bump structure 2420, the first electrode 2410, the second penetration electrode and the second electrode pad 3130.

In various embodiments, when the first and the second external bodies 2100 and 3100 include a chip scale package (CSP), at least two CSPs may be stacked on the circuit board 1000 in a vertical direction, thereby forming a stack package on the circuit board 1000. In the above stack package, the first and the second external bodies 2100 and 3100 may include various semiconductor chips, respectively, according to the requirements of the stack package. For example, the first external body 2100 may include a plurality of dynamic random access memory (DRAM) chips and the second external body 3100 may include flash memory chips, thereby increasing the memory capacity and the operation speed of the semiconductor package 4000. In another embodiment, the first external body 2100 may include a random access memory (RAM) chip and the second external body 3100 may include a read-only memory (ROM) chip, thereby providing a BIOS system as the semiconductor package 4000.

Accordingly, the bump structure 2420 connecting the first and the second external bodies to the circuit board 1000 may make contact with the subsidiary pad 310 as well as with the contact pad 160, thereby increasing the contact reliability between the bump structure 2420 and the circuit board 1000.

Although the circuit board 1000 may be downsized and the pitch of the neighboring contact holes 401 may be decreased, the subsidiary pad 310 may enlarge the contact area between the circuit board 1000 and the bump structure 2420. Therefore, the stack package SP may be mounted on the fine-pitched circuit board 1000 without substantial deterioration of contact reliability between the bump structure 2420 and the circuit board 1000.

Other modifications of the semiconductor package, including the circuit board shown in FIG. 1, various active elements and passive elements, may be mounted on the circuit board 1000. In such an embodiment, a system in package (SIP) may include the circuit board 1000. The active elements such as memory devices and the passive elements such as electrical resistances and electrical condensers may be arranged on the circuit board 1000, thereby forming the SIP. Otherwise, the active elements and the passive elements may be manufactured into a single chip, and the single chip may be mounted onto the circuit board 1000.

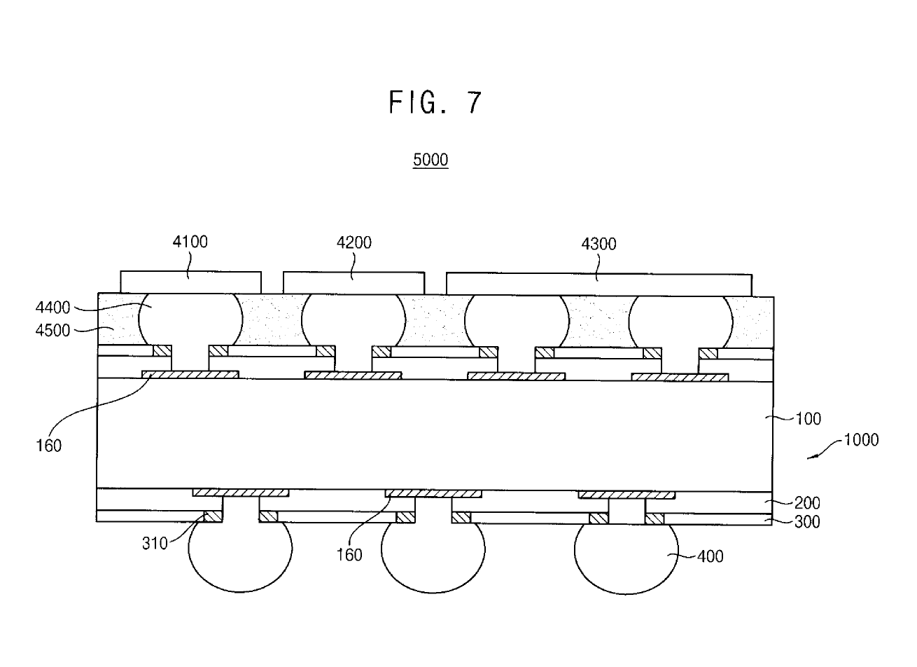

FIG. 7 is a cross-sectional view illustrating a semiconductor package having the circuit board shown in FIG. 1 in accordance with a fourth example embodiment of the present disclosed subject matter.

Referring to FIG. 7, the semiconductor package 5000, in accordance with a fourth example embodiment of the present disclosed subject matter, may include the circuit board 1000 shown in FIG. 1 and a microprocessor package 4100, a resistor-inductor-capacitor (RLC) circuit package 4200 and a memory package 4300 that may be mounted on the circuit board 1000. The microprocessor package 4100, the RLC circuit package 4200 and the memory package 4300 may make contact with the contact pads 160 through the contact holes 401 via contact members 4400, respectively. An under fill layer 4500 may fill, at least partially, the gap spaces between the circuit board 1000 and the microprocessor package 4100, the RLC circuit package 4200 and the memory package 4300. Thus, the microprocessor package 4100, the RLC circuit package 4200 and the memory package 4300 may be bonded to the circuit board 1000 and may be protected, at least partially, from surroundings.

The microprocessor package 4100 may include a chip scale package having a logic circuit, an instruction decoder, a program counter and a control circuit. In such an embodiment, the microprocessor package 4100 may interpret and execute the commands or instructions transferred from the memory package 4300.

The memory package 4300 may store electric data that may be processed by the microprocessor package 4100. For example, the memory package 4200 may include a stack package in which a plurality of DRAM devices or a plurality of flash memory devices may be stacked on a single board, and may include a compound stack package in which both DRAM devices and flash memory devices may be stacked on a single board. Otherwise, the memory package may include a Basic Input-Output System (BIOS) package including a single read-only memory (ROM) device.

The RLC circuit package 4200 may control the currents and voltage of the active elements of the microprocessor package 4100 and the memory package 4300. In such an embodiment, the RLC circuit package 4200 may be configured to control data signals that communicate with the semiconductor package 5000.

For example, the RLC circuit package 4200 may include a plurality of resistors, inductors, registers and/or capacitors that may be individually mounted on the circuit board 1000, and may perform a signal decoupling and filtering and an impedance matching. In addition, the RLC circuit package 4200 may function as a terminator for absorbing signals. In the present example embodiment, the resistors, the inductors, the registers and the capacitors may be stacked into a single stack package and the single RLC stack package may be mounted on the circuit board 1000, thereby reducing the mounting area of the RLC package and decreasing the parasitic capacitance between the resistors, the inductors, the registers and the capacitors with high contact reliability and mounting density of the circuit board 1000.

The contact member 4400 may make contact with the contact pad 160 through the contact hole 401 and with the subsidiary pad 310 on the subsidiary film 300 of the circuit board 1000. Thus, although the circuit board may be downsized and the gap distance between the contact pads 160 may be decreased, the microprocessor package 4100, the RLC package 4200 and the memory package 4300 may be mounted on the circuit board 1000 with a sufficient amount or a certain amount of contact reliability. Accordingly, a larger number of the active elements and the passive elements may be mounted on the circuit board 1000 at high density, thereby manufacturing a high density semiconductor package.

As the recent mobile systems tend to be light and thin together and also provide high performance, the application processor (AP) for the recent mobile systems often make use of a small occupancy area and a high operation speed. When the present example embodiment of the SIP may be applied to the mobile AP, the contact reliability of various component packages of the mobile AP to the circuit board 1000 may be increased in spite of the downsizing and pitch reduction of the circuit board, thereby increasing the system reliability of the mobile system.

Electronic System Having the Semiconductor Package

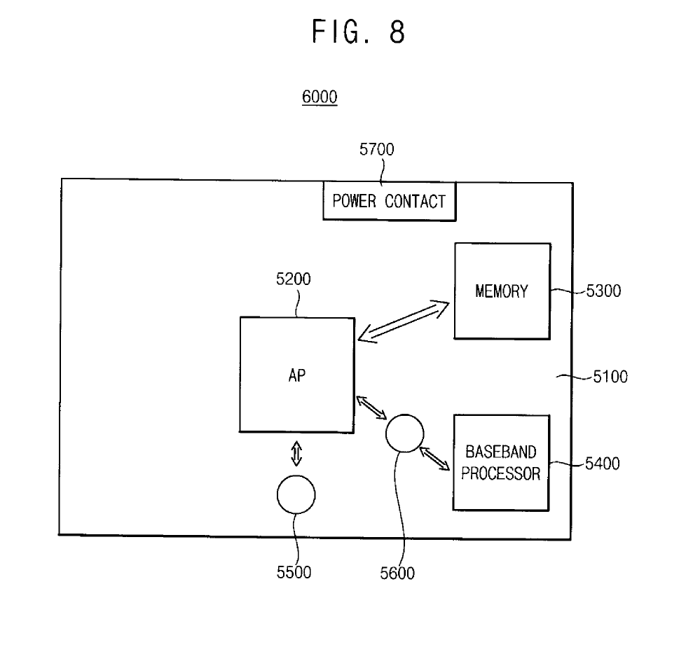

FIG. 8 is a structural view illustrating an electronic system having the semiconductor package using the circuit board shown in FIG. 1 in accordance with an example embodiment of the present disclosed subject matter. In FIG. 8, a mobile electronic system, such as a smart phone and a table personal computer (PC), may be exemplarily disclosed as the electronic system in which operation unit modules around an application processor (AP) may be provided on the circuit board shown in FIG. 1. However, various electronic systems as well as the mobile system would include the semiconductor package using the circuit board 1000 shown in FIG. 1 as the operation modules thereof.

Referring to FIG. 8, the electronic system 6000 in accordance with an example embodiment of the present disclosed subject matter may include a base board 5100, an application processor (AP) 5200. In various embodiments, the AP 5200 may be arranged on the base board 5100 and electrically connected to the base board 5100. In some embodiments, the electronic system 6000 may include a memory module 5300, a baseband processor 5400 and a controller 5500 that may be in communication with the AP 5200. Further, the electronic system 6000 may include a process inter-connector 5600 configured to transmit signals between the AP 5200 and BP 5400 and a power connector 5700.

The base board 5100 may have substantially the same structure as the circuit board shown in FIG. 1 and the same reference numerals denote the same elements of the circuit board 1000. Thus, the contact pad 160 for connecting the internal circuit of the base board 5100 with the external body may be exposed through the contact hole 401 and the subsidiary pad 310 may be arranged around the contact hole 401. The contact pad 160 may be covered, at least partially, with the mask pattern 200, and the subsidiary film 300 together with the subsidiary pad 310 may be arranged on the mask pattern 200. The AP 5200, the memory module 5300, the baseband processor 5400, the controller 5500, the process inter-connector 5500 and the power contact 5700 may make contact with the contact pads 160 through the contact hole 401 of the base board 5100 and may be bonded to the base board 5100 with high stability. Thus, the contact area between the base board 5100 and the external bodies such as the AP 5200, the memory module 5300, the baseband processor 5400 and the controller 5500 may be enlarged as much as an upper surface of the subsidiary pad 310, thereby increasing the contact reliability of the external bodies to the base board 5100.

The AP 5200 may include a central processing unit (CPU) operating and executing instructions. The AP 5200 may include a first controller for controlling the data communication between the CPU and memory chips thereof and a second controller for controlling the data communication between the CPU and the peripheral modules around the AP 5200.

Raw data may be transferred to the AP 5200 from the memory module 5300 and the processed data by the AP 5200 may be transferred again to the memory module 5300 from the AP 5200 in accordance with the operation of the electronic system 6000. The AP 5200 and the memory module 5300 may be horizontally arranged on the base board 5100. Otherwise, the AP may be arranged on the base board 5100 and the memory module 5300 may be stacked on the AP 5200.

The baseband processor (BP) 5400 may enable the electronic system 6000 to communicate with a base station or other device, to thereby transfer data through a wireless data communication between electronic systems. When the electronic system 6000 receives the data through the wireless data communication, the received data may be processed by the AP 5200 and thus the electronic system 6000 may perform according to the results of the data processing at the AP 5200. In one embodiment, when the data type of the AP 5200 may be different from that of the BP 5400, the process inter-connector 5600 may synchronize the data between the AP 5200 and the BP 5400.

The controller 5500 may include various audio codecs and various input/output controllers such as an input controller for a touch panel. Thus, the controller 5500 may play music data and moving picture or video data processed by the AP 5200 on a display unit (not shown) of the electronic system 6000 and the input signals from a touch panel (not shown) may be transferred to the AP 5200 by the controller 5500. The power contact 5700 may be connected to an inner battery (not shown) of the electronic system 6000 and may apply electric power to the operation modules of the electronic system 6000. It is understood that the above are merely a few illustrative examples to which the disclosed subject matter is not limited.

According to the above electronic system, the contact area between the base board 5100 and the external bodies such as the AP 5200, the memory module 5300, and BP 5400 may be increased as much as the surface of the subsidiary pad. In such an embodiment, the contact reliability between the base board and the external bodies may be increased in spite of the size and pitch reduction of the base board. In addition, the subsidiary film, having the subsidiary pad, may further absorb the external disturbances such as a physical shock or impact and thus the internal circuit of the base board may be protected, at least partially, from its surroundings. Thus, a larger number of external bodies may be mounted on the base board and the electronic system may be downsized without substantial deterioration of performance thereof.

According to example embodiments of the present disclosed subject matter of the circuit board and the semiconductor package using the circuit board, the contact pad may be exposed through the contact hole penetrating the mask pattern and the subsidiary film, and the subsidiary pad may be provided around the contact hole. Thus, the external body may make contact with the subsidiary pad as well as the contact pad of the circuit board, so that the contact area between the circuit board and the external body may be enlarged as much as the upper surface area of the subsidiary pad. Therefore, the external body may be secured to the circuit board with high stability and reliability. In addition, the circuit pattern of the circuit board may also be protected from surroundings by the subsidiary film and the subsidiary pad.

Although the size and the pitch of the circuit board may be reduced while increasing the number of the external bodies mounted onto the circuit board, the contact area between the external body and the circuit board may be provided due to the subsidiary pad. Therefore, the external body may be bonded to the high density circuit board with high stability and thus the semiconductor package using the circuit board and the electronic system having the semiconductor package may have high reliability.

The present example embodiments of the memory device may be applied to various electronic systems including semiconductor devices and IC chips such as telecommunication systems and storage systems.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present disclosed subject matter. Accordingly, all such modifications are intended to be included within the scope of the present disclosed subject matter as defined in the claims. In the claims, means-plus-function clauses are intended to cover the structures described herein as performing the recited function and not only structural equivalents, but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A circuit board comprising:
a body having an internal circuit pattern and a plurality of contact pads connected to the internal circuit pattern;
a mask pattern positioned on the body such that the circuit pattern and the contact pads are covered, at least partially, with the mask pattern, the mask pattern having at least a first opening through which the contact pad is at least partially exposed;
a subsidiary film positioned on the mask pattern and having at least a subsidiary pad, the subsidiary film having at least a second opening connected with the first opening to form a contact hole and the subsidiary pad being arranged around the second opening to substantially enclose the second opening; and
a contact terminal positioned on the subsidiary film such that the contact hole is filled, at least partially, with the contact terminal and the subsidiary pad is covered, at least partially, with the contact terminal, such that the contact terminal makes contact with both of the contact pad and the subsidiary pad.

2. The circuit board of claim 1, wherein the mask pattern includes a solder resist pattern.

3. The circuit board of claim 1, wherein the subsidiary film is arranged on the mask pattern in a configuration such that the second opening is connected with the first opening and the subsidiary pad includes a ring shape enclosing the second opening at an upper portion of the subsidiary film.

4. The circuit board of claim 3, wherein the subsidiary pad is arranged on the mask pattern around the second opening in a configuration such that the subsidiary pad protrudes from the subsidiary film with a stepped portion and the contact hole is extended to an extended opening penetrating through the ring shape of the subsidiary pad.

5. The circuit board of claim 4, further comprising a buffer film positioned on the subsidiary film in a configuration such that an upper surface of the buffer film is substantially coplanar with an upper surface of the subsidiary pad.

6. The circuit board of claim 3, wherein the subsidiary film includes a recess holding the second opening and the subsidiary pad is filled into the recess in a configuration such that the second opening is defined by the subsidiary pad.

7. The circuit board of claim 1, wherein the subsidiary film includes at least one of a polyimide film, a polyoxazole film, a polyamide film or a polyester film and, wherein the subsidiary pad includes an electroless plating layer comprising at least one material selected from the group consisting of gold (Au), silver (Ag), copper (Cu), aluminum (Al), nickel (Ni) and combinations thereof.

8. The circuit board of claim 1, wherein the contact terminal includes solder balls that makes contact with the contact pads, respectively, in a matrix shape.

9. The circuit board of claim 1, wherein the internal circuit pattern includes:
a signal line electrically connecting two contact terminals with another contact terminal,
a power line configured to transmit a power for driving the signal line,
a ground line configured to provide an electrical ground for the signal line, and
a vertical interconnector penetrating through the body and making contact with an upper signal line arranged on an upper surface of the body and a lower signal line arranged on a lower surface of the body.

10. The circuit board of claim 9, wherein the signal line has a width of between 15 nm to 25 nm and the signal line is arranged, with respect to another signal line, at a gap distance of between 15 nm to 25 nm; and
wherein the contact pad has a width of between 65 nm to 75 nm and is spaced apart from the signal line at a gap distance of between 15 nm to 25 nm.

11. A semiconductor package comprising:
a circuit board including:
a body having an internal circuit pattern and a plurality of contact pads connected to the internal circuit pattern,
a mask pattern positioned on the body such that the circuit pattern and the contact pads are covered, at least partially, with the mask pattern and the mask pattern having at least a first opening through which the contact pad is at least partially exposed,
a subsidiary film positioned on the mask pattern and having at least a subsidiary pad such that the subsidiary film has at least a second opening that provides access to the first opening to thereby provide a contact hole, wherein the subsidiary pad is arranged around the second opening to enclose, at least partially, the second opening, and
a contact terminal positioned on the subsidiary film such that the contact hole is filled, at least partially, with the contact terminal and the subsidiary pad is covered, at least partially, with the contact terminal, so that the contact terminal makes contact with both of the contact pad and the subsidiary pad;
a plurality of additional contact terminals respectively positioned opposite to the plurality of the contact terminals of the circuit board and making contact with both of the contact pad and the subsidiary pad; and
at least one external body having an integrated circuit device and making contact with at least one additional contact terminal.

12. The semiconductor package of claim 11, wherein the external body includes a semiconductor chip having the integrated circuit device; and
the additional contact terminal includes a bump structure bonded to an active surface of the semiconductor chip, so that the external body and the additional contact terminal are configured as a flip chip structure on the circuit board.

13. The semiconductor package of claim 11, wherein the external body includes a semiconductor chip having the integrated circuit device; and
the additional contact terminal includes a penetration electrode penetrating through a substrate of the semiconductor chip, and connected to a electrode pad of the semiconductor chip and a bump structure making contact with the penetration electrode at a rear surface of the semiconductor chip, so that the external body and the additional contact terminal are included as part of a chip scale package on the circuit board.

14. The semiconductor package of claim 13, wherein the external body includes a plurality of stacked semiconductor chips and each electrode pad of the semiconductor chips is electrically connected with each other by the penetration electrode, so that the external body and the additional contact terminal are provided into a stack package on the circuit board.

15. The semiconductor package of claim 11, wherein the external body includes an active element and a passive element coupled with the circuit board.

16. An apparatus comprising:
a contact terminal disposed, at least partially, within a contact hole, wherein the contact hole is disposed through a subsidiary film and a mask pattern;
a subsidiary pad disposed between the subsidiary film and the contact terminal and disposed at an external opening of the contact hole;
a contact pad terminating an internal opening of the contact hole and disposed within the mask pattern; and
wherein the contact terminal is electrically coupled with the contact pad and having a contact reliability based, at least in part, upon the subsidiary pad.

17. The apparatus of claim 16, wherein a contact area associated with the contact terminal is based upon a width of the contact hole plus an upper surface of the subsidiary pad.

18. The apparatus of claim 16, wherein the contact hole includes an inner wall comprised of an inner wall of the subsidiary pad and an inner wall of the subsidiary film; and
wherein the inner wall of the subsidiary pad and the inner wall of the subsidiary film are substantially coplanar.

19. The apparatus of claim 16, further comprising a buffer film disposed on the subsidiary film, and next to the subsidiary pad; and wherein the buffer film includes an external surface that is substantially coplanar with an external surface of the subsidiary pad.

20. The apparatus of claim 16, further comprising an external body electrically coupled with the contact terminal; and
wherein the contact terminal is disposed between the subsidiary pad and the external body.
